(19) United States
(12) Patent Application Publication
(10) Pub. No.: US 2015/0049779 A1
(43) Pub. Date: Feb. 19, 2015

(54) SEMICONDUCTOR LASER OPTICAL DEVICE

(71) Applicant: Ushio Denki Kabushiki Kaisha, Tokyo (JP)

(72) Inventor: Toru Kontani, Hyogo (JP)

(21) Appl. No.: 14/388,813

(22) PCT Filed: Mar. 12, 2013
(86) PCT No.: PCT/JP2013/056722

§ 371 Date: Sep. 28, 2014

(30) Foreign Application Priority Data
Apr. 3, 2012 (JP) 2012-084830

(51) Int. Cl. H01S 5/10; G02B 27/30

(52) U.S. Cl. CPC H01S 5/10; G02B 27/30
USPC 372/101

(57) ABSTRACT

Disclosed is a semiconductor laser optical device that can suppress the occurrence of crosstalk light to obtain high collimating efficiency and is relatively inexpensive and compact. This semiconductor laser optical device includes: a laser source that includes a semiconductor laser element; a first collimator lens that is provided on a laser light emission side of the laser source and collimates a light component diverging in a fast-axis direction of laser light emitted from the laser source; and a second collimator lens that is provided on an emission side of the first collimator lens and collimates a light component diverging in a slow-axis direction of light emitted from the first collimator lens. The first collimator lens has a function of making light of which spreading in the slow-axis direction is suppressed incident on the second collimator lens.

### TECHNICAL FIELD

The present invention relates to a semiconductor laser optical device. More specifically, the present invention relates to, for example, a semiconductor laser optical device including a collimator lens structure that can efficiently collimate laser light emitted from a laser source including a high-output array type semiconductor laser element.

### BACKGROUND ART

A laser source is desired to be able to emit a highly-collimated (highly-parallel) beam so that, for example, the light emitted from the semiconductor laser element can be condensed by an appropriate optical member and efficiently made incident on a core part of a small-diameter optical fiber.

Examples of known semiconductor laser elements include an array type one in which a plurality of emitters are arranged. An array type semiconductor laser element is typically configured as an edge emission type, and an optical output of, for example, several watts or more is demanded.

According to such a semiconductor laser element, in a fast-axis direction which is a direction perpendicular to the pn junction interface, single mode light spreading widely is emitted because the thickness of the active layer, or the dimension of each emitter in the fast-axis direction, is sufficiently small. In contrast, in a slow-axis direction which is a direction parallel to the pn junction interface, narrowly spreading multimode light is emitted because the active layer has a large width, or equivalently, the dimension of each emitter in the slow-axis direction is large. And so, light components diverging in the slow-axis direction have low beam quality as compared with light components diverging in the fast-axis direction and are light less easier to collimate.

For example, a technique illustrated in FIG. 8 has been known as a technique for collimating laser light emitted from a laser source including such an array type semiconductor laser element. In FIG. 8, light components diverging in the fast-axis direction (direction perpendicular to the diagram, or Y-axis direction) of laser light emitted from a semiconductor laser element 11 in which a plurality of emitters 12 are arranged in a row in the slow-axis direction (X-axis direction) are collimated by a fast-axis direction collimator lens 40. Light components diverging in the slow-axis direction (X-direction) of the light emitted from this fast-axis direction collimator lens 40 are further collimated by a slow-axis direction collimator lens 50. Here, for example, one having a structure in which a plurality of lens elements 51 corresponding to the respective emitters 12 of the semiconductor laser element 11 are arranged in a row in the slow-axis direction (X-axis direction) is used as the slow-axis direction collimator lens 50. The symbols C in FIG. 8 represent the optical axes of the emitters 12.

As a method for improving collimating properties in the slow-axis direction, for example, there has been known a technique in which means for dividing beams in the fast-axis direction are provided between the fast-axis direction collimator lens and the slow-axis direction collimator lens (see Patent Literature 1).

### CITATION LIST

### Patent Literature

Patent Literature 1: Japanese Translation of PCT Patent Application Publication No. Hei 10-508122

### SUMMARY OF INVENTION

### Technical Problem

However, the one configured by arranging the fast-axis direction collimator lens 40 and the slow-axis direction collimator lens 50 has the following problem. That is, as illustrated in FIG. 8(b), in a plane seen in the fast-axis direction (X-Z plane), the laser light incident on a lens element 51b of the slow-axis direction collimator lens 50 that is opposed to one emitter 12 of the semiconductor laser element 11 and corresponds to the emitter 12 is incident on adjoining lens elements 51a and 51c. As illustrated by the dashed double-dotted lines in FIGS. 8(a) and 8(b), relatively low-angle components of light are incident on the predetermined lens element 51b and collimated in the slow-axis direction. However, as illustrated by the broken lines in FIGS. 8(a) and 8(b), relative high-angle components of light are incident on the adjoining lens elements 51a and 51c on both sides of the predetermined lens element 51b. There is thus a problem in which the light emitted from the slow-axis direction collimator lens 50 diverges (hereinafter, referred to as “crosstalk”).

The semiconductor laser element 11 is configured so that the plurality of emitters 12 are arranged in a row at predetermined intervals in the slow-axis direction. To perform efficient collimation in the slow-axis direction, the following arrangement is needed. That is, the slow-axis direction collimator lens 50 needs to be arranged so that the incident surfaces of the respective lens elements 51 of the slow-axis direction collimator lens 50 are on the semiconductor laser element 11 side of a position where the laser beams emitted from the respective adjoining emitters 12 overlap each other after emitted from the fast-axis direction collimator lens 40. Such a positional relationship, however, has the problem that the collimating properties in the slow-axis direction become worse than the collimating properties in the fast-axis direction.

Moreover, according to the technique described in the foregoing Patent Literature 1, the laser beams emitted from the respective adjoining emitters are collimated by the fast-axis direction collimator lens and emitted from the fast-axis direction collimator lens with a change in height in the fast-axis direction. Since the beams emitted from the respective emitters in the slow-axis direction do not overlap, there is an advantage that the lens diameter of the slow-axis direction collimator lens can be set without considering the overlapping of the laser beams emitted from the adjoining emitters. There is a problem, however, in which the optical system is complicated and becomes a relatively large structure itself.

The present invention has been made in view of the foregoing circumstances and has as its object the provision of a semiconductor laser optical device that can suppress the occurrence of crosstalk light to obtain high collimating efficiency, can be fabricated relatively inexpensively and is compact.

### Solution to Problem

A semiconductor laser optical device according to the present invention is a semiconductor laser optical device including: a laser source that includes a semiconductor laser element; a first collimator lens that is provided on a laser light emission side of the laser source and collimates a light component diverging in a fast-axis direction of laser light emitted from the laser source; and a second collimator lens that is provided on an emission side of the first collimator lens and collimates a light component diverging in a slow-axis direction of light emitted from the first collimator lens, wherein

the first collimator lens has a function of making light of which spreading in the slow-axis direction is suppressed incident on the second collimator lens.

In the semiconductor laser optical device according to the present invention, the first collimator lens may have a spreading suppression function portion at a fringe area in the slow-axis direction in either one or both of an incident surface and an emission surface thereof.

In the semiconductor laser optical device according to the present invention, one in which a plurality of emitters are arranged in a row may be used as the semiconductor laser element constituting the laser source.

### Advantageous Effects of Invention

In the semiconductor laser optical device according to the present invention, the first collimator lens that collimates the light component diverging in the fast-axis direction of the laser light emitted from the laser source has the function of making light of which the spreading in the slow-axis is suppressed incident on the second collimator lens. And so, according to the semiconductor laser optical device of the present invention, light components that diverge at large angles of divergence and can become crosstalk light among light components diverging in the slow-axis direction can be deflected and corrected toward an optical axis side. In addition, the laser light emitted from the first collimator lens is capable of being sufficiently collimated in the slow-axis direction by the second collimator lens. And so, the occurrence of crosstalk light can be suppressed to obtain high collimating efficiency. Moreover, the collimating properties can be improved without using other optical members such as a beam splitter and a deflection mechanism. Consequently, a semiconductor laser optical device having desired performance can be fabricated with a small parts count in a cost advantageous manner, and the device itself can be configured in a small size.

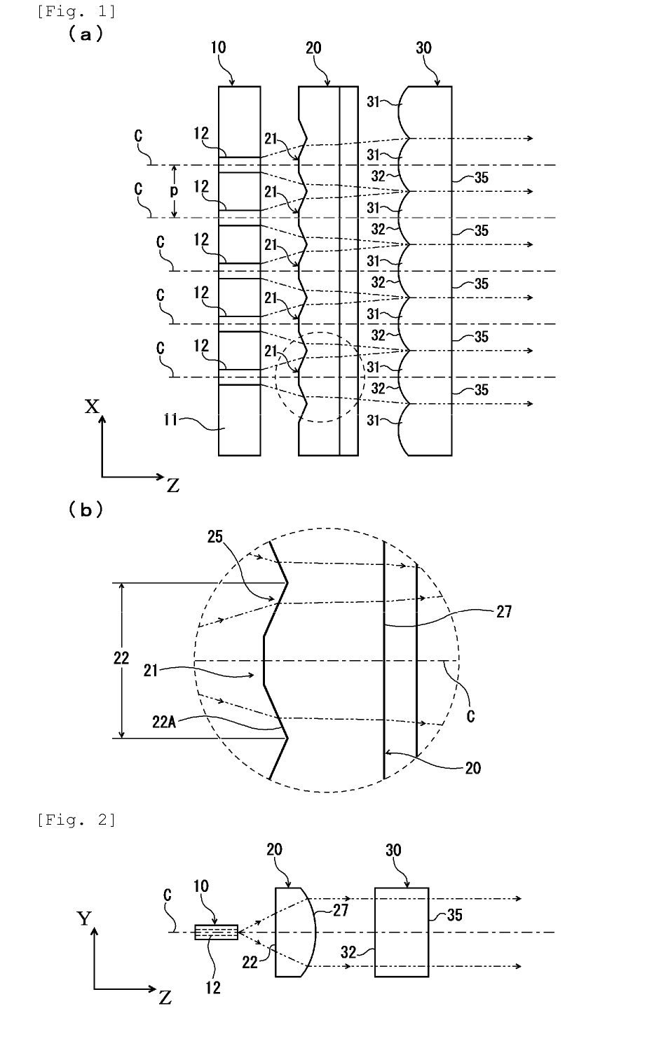

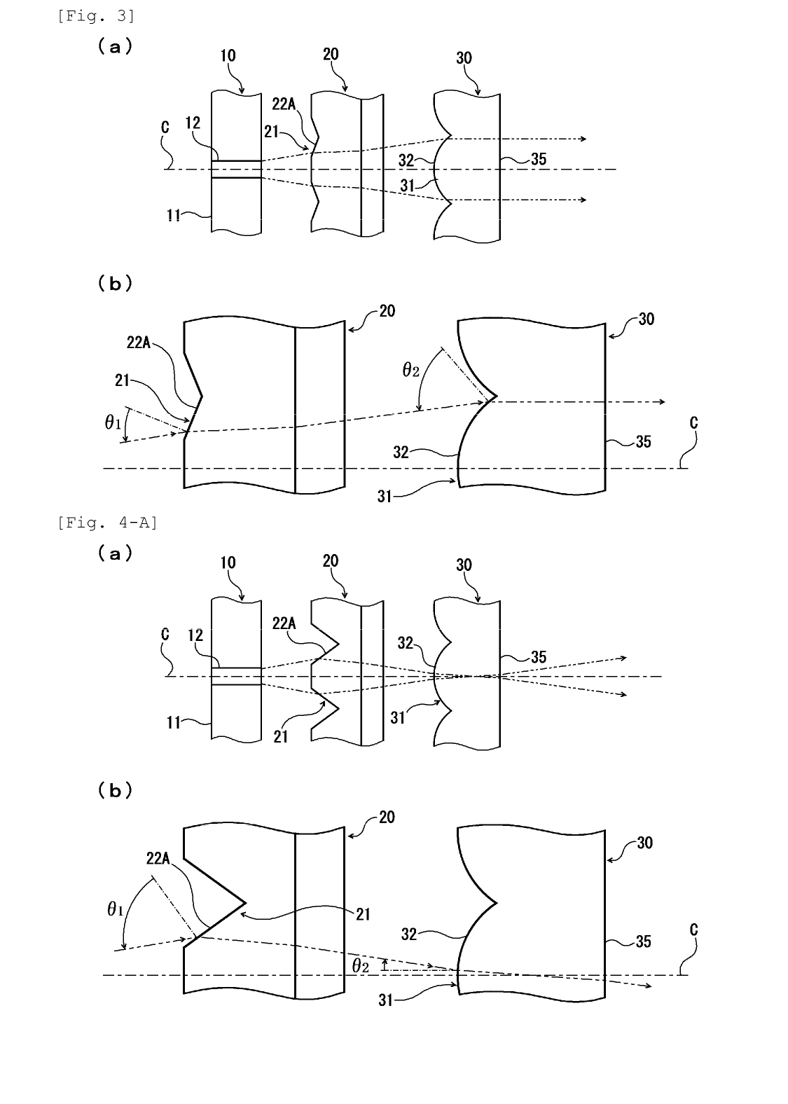

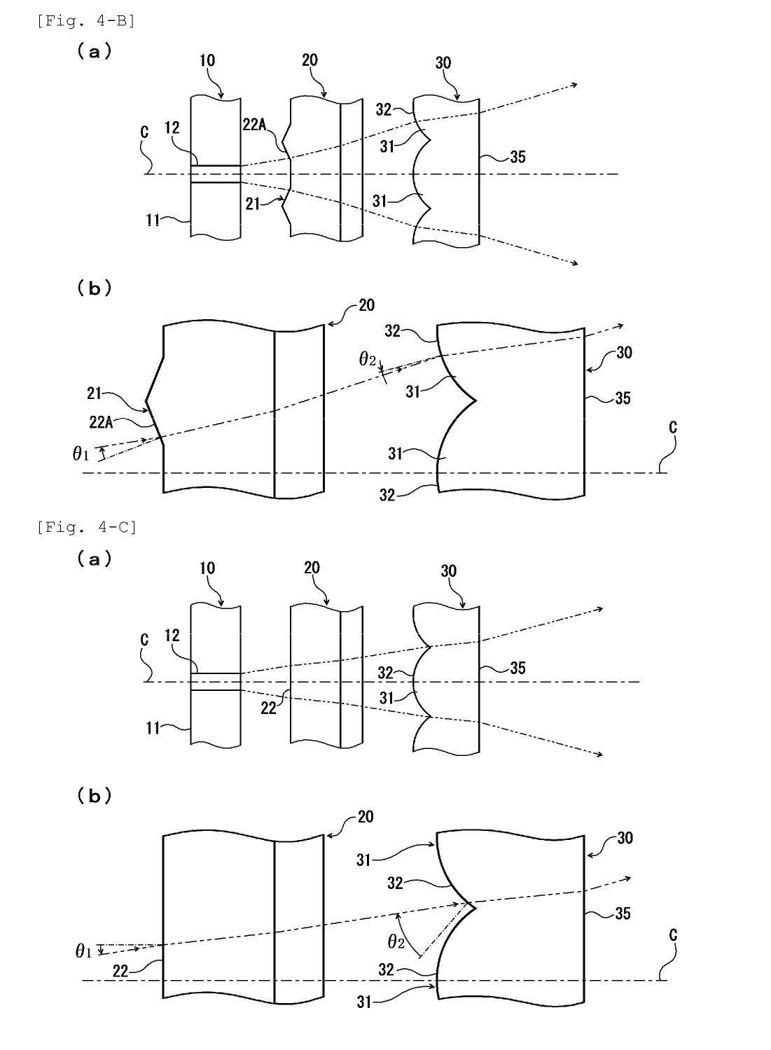

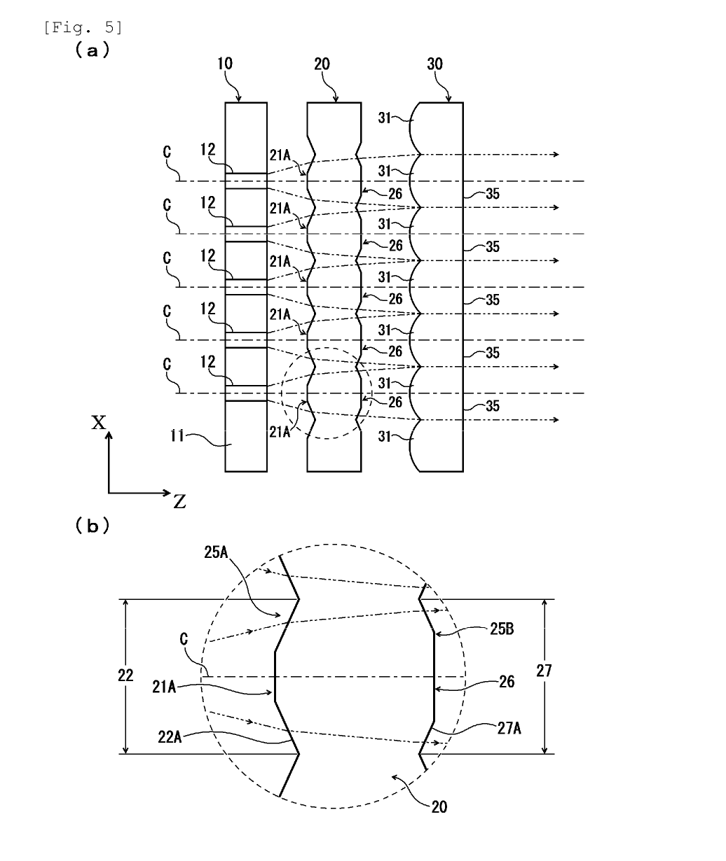

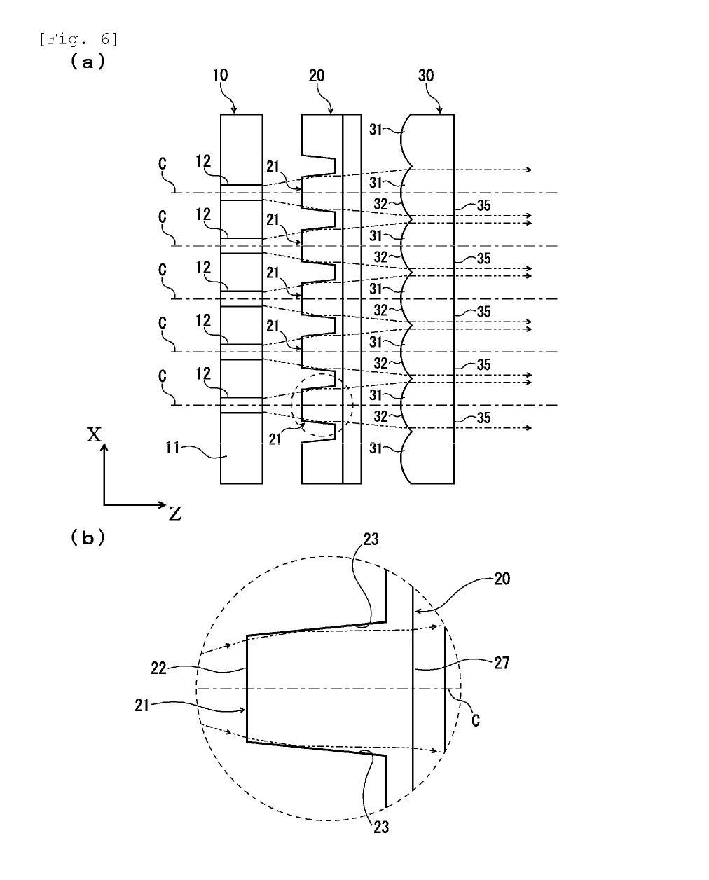

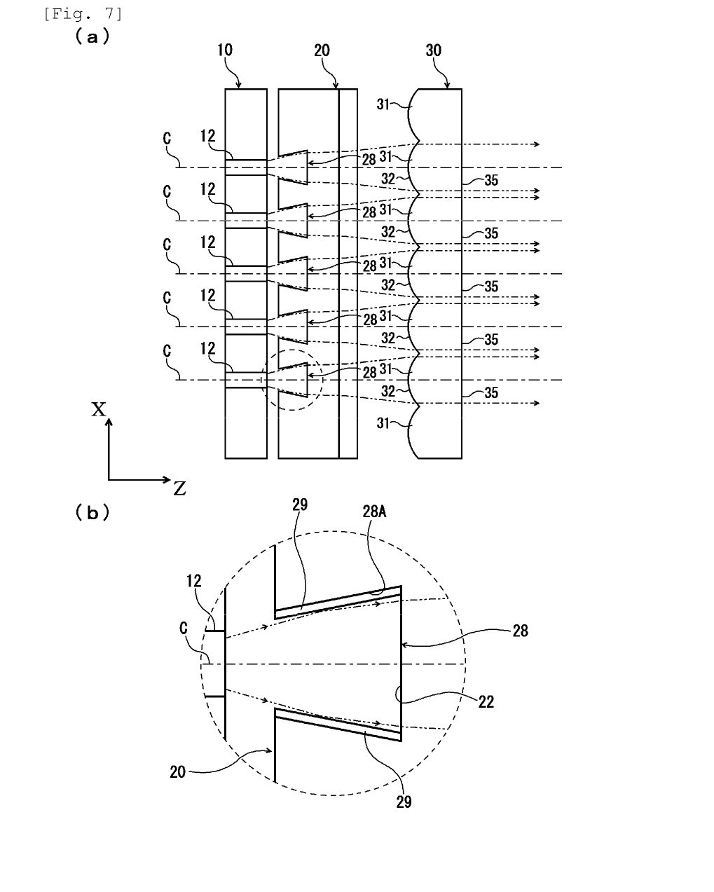

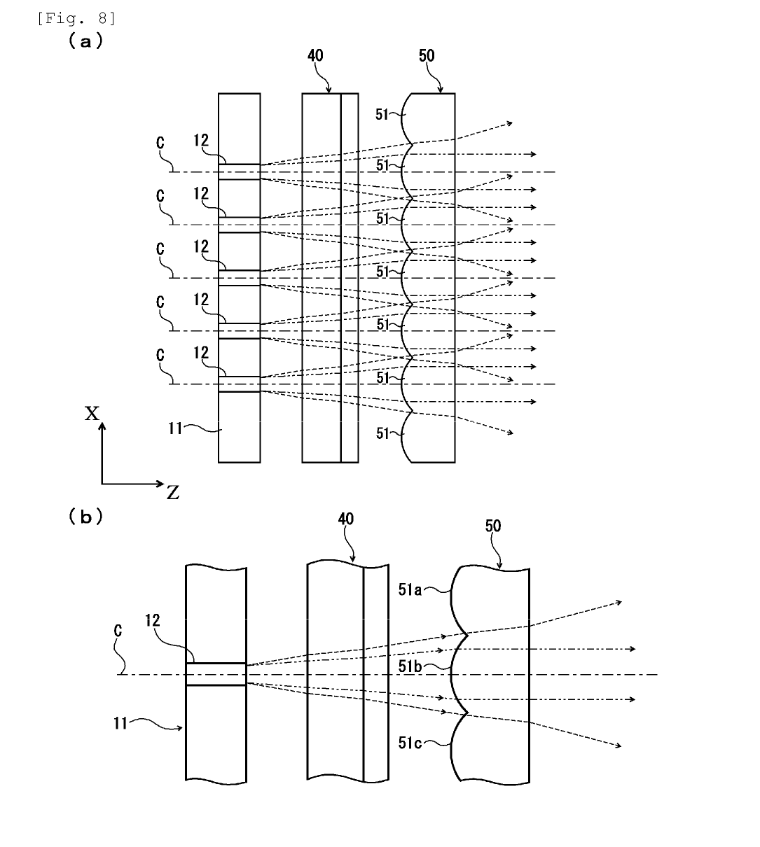

### BRIEF DESCRIPTION OF DRAWINGS

[FIG. 1] is a diagram schematically illustrating a configuration example of a semiconductor laser optical device according to a first embodiment of the present invention.

[FIG. 2] is a plan view of the semiconductor laser optical device illustrated in FIG. 1, seen in a slow-axis direction.

[FIG. 3] is a diagram enlarging and illustrating part of the semiconductor laser optical device illustrated in FIG. 1.

[FIG. 4-A] is a diagram illustrating a first comparative example of the semiconductor laser optical device illustrated in FIG. 1, where the sign of the inclination of the angle of light incident on a concave inclined surface differs from the sign of the inclination of the angle of light incident on a lens element of a second collimator lens.

[FIG. 4-B] is a diagram illustrating a second comparative example of the semiconductor laser optical device illustrated in FIG. 1, where the sign of the inclination of the angle of light incident on a concave inclined surface differs from the sign of the inclination of the angle of light incident on a lens element of the second collimator lens.

[FIG. 4-C] is a diagram illustrating a third comparative example of the semiconductor laser optical device illustrated in FIG. 1, where the sign of the inclination of the angle of light incident on a concave inclined surface differs from the sign of the inclination of the angle of light incident on a lens element of the second collimator lens.

[FIG. 5] is a diagram schematically illustrating a configuration example of a semiconductor laser optical device according to a second embodiment of the present invention.

[FIG. 6] is a diagram schematically illustrating a configuration example of a semiconductor laser optical device according to a third embodiment of the present invention.

[FIG. 7] is a diagram schematically illustrating a configuration example of a semiconductor laser optical device according to a fourth embodiment of the present invention.

[FIG. 8] is a diagram schematically illustrating a configuration example of a conventional semiconductor laser optical device.

### DESCRIPTION OF EMBODIMENTS

Hereinafter, embodiments of the present invention will be described in detail.

### First Embodiment

FIG. 1 is a diagram schematically illustrating a configuration example of a semiconductor laser optical device according to a first embodiment of the present invention. FIG. 1(a) is a plan view taken in a fast-axis direction. FIG. 1(b) is an enlarged view illustrating the area circled by the broken line in FIG. 1(a). FIG. 2 is a plan view of the semiconductor laser optical device illustrated in FIG. 1, seen in a slow-axis direction.

This semiconductor laser optical device includes a laser source 10 including a semiconductor laser element 11, a first collimator lens 20 provided on a laser light emission side of this laser source 10, and a second collimator lens 30 provided on an emission side of this first collimator lens 20. The first collimator lens 20 has a function of collimating light components diverging in the fast-axis direction (Y-axis direction) of the laser light (illustrated by dashed double-dotted lines) emitted from the laser source 10. The second collimator lens 30 has a function of collimating light components diverging in the slow-axis direction (X-axis direction) of the light emitted from the first collimator lens 20.

For example, the laser source 10 includes the semiconductor laser element 11 in which a plurality (in this example, five) of emitters 12 each having a large width in the slow-axis direction are arranged in a row at predetermined intervals in the slow-axis direction.

The semiconductor laser element 11 is an edge emitting type, for example. In such a semiconductor laser element 11, laser light is emitted from an end surface of each emitter 12 perpendicular to the pn junction interface of the semiconductor laser element 11, with predetermined angles of divergence in the slow-axis direction and the fast-axis direction with respect to the optical axis (illustrated by a dashed dotted line) C of the emitter 12.

In one configuration example, the semiconductor laser element 11 has external dimensions of 4 mm×0.1 mm×1.5 mm (X-axis direction×Y-axis direction×Z-axis direction). One end surface of each emitter 12 from which the laser light is emitted (laser light emission edge) has dimensions of 40 μm×1 μm (X-axis direction×Y-axis direction). The center-to-center distance (arrangement pitch) p between adjoining emitters is 200 μm, the oscillation wavelength is 634 to 644 nm, the angle of divergence in the fast-axis direction with respect to the optical axis is 40° in the total angle at half maximum and the angle of divergence in the slow-axis direction is 7° in the total angle at half maximum.

The first collimator lens 20 has a function of deflecting light components of the laser light that are emitted from the emitters 12 of the semiconductor 11 and diverge in the fast-axis direction with respect to the optical axes C of the emitters 12, toward the optical axis C side of the emitters 12 and thereby collimating the light components in the fast-axis direction. In other words, the first collimator lens 20 collimates the laser light emitted from the emitters 12 into parallel light with respect to the optical axes of the emitters 12 in the Y-Z plane.

This first collimator lens 20 is arranged close to the laser source 10 so that the optical axes coincide with those of the semiconductor laser element 11.

The second collimator lens 30 has a function of deflecting light components of the laser light that are emitted from the first collimator lens 20, pertain to the respective emitters 12, and diverge in the slow-axis direction with respect to the optical axes of the emitters 12, toward the optical axis C side of the emitters 12 and thereby collimating the light components in the slow-axis direction. In other words, the second collimator lens 30 collimates the laser light collimated in the fast-axis direction, emitted from the first collimator lens 20, into parallel light with respect to the optical axes of the emitters 12 in the X-Z plane.

In this example, the second collimator lens 30 is configured, for example, so that a plurality of lens elements 31 corresponding to the plurality of respective emitters 12 of the semiconductor laser element 11 are arranged in the slow-axis direction. Incident surfaces 32 of the respective lens elements 31 are opposed to an emission surface 27 of the first collimator lens 20 so that the optical axes of the second collimator lens 30 coincide with the optical axes of the semiconductor laser element 11. The lens elements 31 each include, for example, a plano-convex cylindrical lens having a refracting surface made of a convex cylindrical surface on the first collimator lens 20 side, with a flat surface configured as an emission surface 35.

Thus, the first collimator lens 20 constituting the semiconductor laser optical device described above has a function of making light of which spreading in the slow-axis direction is suppressed incident on the second collimator lens 30 (hereinafter, referred to as a “slow-axis direction deflection correction function”).

The first collimator lens 20 has spreading suppression function portions 25 at fringe areas in the slow-axis direction in incident surfaces 22 on which the laser light emitted from the respective emitters 12 is incident. Specifically, the first collimator lens 20 is formed so that, in the X-Z plane, V-shaped groove portions extend in the fast-axis direction in parallel with each other at areas of the flat surface of the plano-convex cylindrical lens opposed to the respective areas between the adjoining emitters. As a result, a plurality of deflection correction lens portions 21 having respective trapezoidal incident surfaces 22 are formed in the areas between the adjoining groove portions. The deflection correction lens portions 21 are arranged in one example in the slow-axis direction with respect to the respective emitters 12.

Concave inclined surfaces 22A of the respective deflection correction lens portions 21 constitute the spreading suppression function portions 25. Here, one deflection correction lens portion 21 has a dimension in the slow-axis direction smaller than, for example, the arrangement pitch p of the emitters 12 in the slow-axis direction with respect to the optical axis C of an emitter 12.

In this first collimator lens 20, light components of the laser light emitted from one emitter 12, diverging at relatively large angles of diversion in the slow-axis direction while traveling, are incident on the concave inclined surfaces 22A of the deflection correction lens portion 21 corresponding to the emitter 12. High-angle light components incident on the concave inclined surfaces 22A are deflected toward the optical axis C side of the emitter 12 and emitted as low-angle light components of which the angle of divergence in the slow-axis direction is suppressed to be small. Here, “high-angle light components” in the slow-axis direction refer to light components that diverge at angles greater than ±5.8° with respect to the optical axis C of the emitter 12. “Low-angle light components” refers to light components that diverge at angles within a range of ±5.8° with respect to the optical axis C of the emitter 12.

The concave inclined surfaces 22A of the deflection correction lens portions 21 have an inclination angle such that the laser light from the respective emitters 12 is incident on the corresponding lens elements 31 of the second collimator 30 and the laser light pertaining to each emitter 12 emitted from the second collimator lens 30 becomes generally parallel to the optical axis C of the emitter 12.

The inclination angle of the concave inclined surfaces 22A of each deflection correction lens portion 21 will be concretely described with reference to FIG. 3. The inclination angle of a concave inclined surface 22A of the deflection correction lens portion 21 is set to an angle range such that the sign (the direction of the arrow) of the inclination of an angle θ1 of incident light with respect to the concave inclined surface 22A coincides with the sign of the inclination of an angle θ2 of light incident on the incident surface 32 of the corresponding lens element 31 of the second collimator lens 30 in a plane seen in the fast-axis direction (X-X plane).

If the sign of the inclination of the angle θ1 of light incident on the convex inclination surface 22A is different from the sign of the inclination of the angle θ2 of light incident on the lens element 31 of the second collimator lens 30, like illustrated in FIGS. 4-A and 4-B as comparative examples, the laser light emitted from the second collimator lens 30 does not become parallel to the optical axis C of the emitter 12. In particular, in the configuration illustrated in FIG. 4-B, the laser light fails to be made incident on the corresponding lens element 31 of the second collimator lens 30 and becomes crosstalk light. As illustrated in FIG. 4-C as a comparative example, even if the first collimator lens 20 has a flat incident surface 22, the same applies as with the configuration illustrated in FIG. 4-B. Specifically, the sign (the direction of the arrow) of the inclination of the angle θ1 of light incident on the flat incident surface 22 of the first collimator lens 20 is different from the sign of the inclination of the angle θ2 of light incident on the corresponding lens element 31 of the second collimator lens 30. Consequently, the laser light fails to be made incident on the corresponding lens element 31 of the second collimator lens 30 and becomes crosstalk light.

For example, suppose that the separation distance in the optical axis direction (Z-axis direction) between the flat surface at the incident surface 22 of the first collimator lens 20 and the edge of the emitter 12 from which the laser light is emitted is 0.16 mm. The dimension of the first collimator lens 20 in the optical axis direction is 1 mm. The refractive index of the first collimator lens 20 is 1.78. The minimum separation distance in the optical axis direction (Z-axis direction) between the incident surface 32 of each lens element 31 of the second collimator lens 30 and the emission surface 27 of the first collimator lens 20 is 0.4 mm. Each lens element 31 of the second collimator lens 30 has a radius of curvature of 0.81 mm. The refractive index of the second collimator lens 30 is 1.81. The angle θ1 of light incident on the convex inclined surfaces 22A of the first collimator lens 20 is 7.5 to 10.8°. In such a case, the inclination angle of the convex included surfaces 22A forming the spreading suppression function portions 25 may preferably fall within an angle range of not greater than 5°.

Thus, the semiconductor laser optical device of the foregoing configuration includes the laser source 10 including the semiconductor laser element 11 in which the plurality of emitters 22 are arranged in a row in the slow-axis direction. With such a configuration, light components diverging in the fast-axis direction of the laser light emitted from the laser source 10 are collimated by the first collimator lens 20. This first collimator lens 20 is configured so that the plurality of deflection correction lens portions 21 having the spreading suppression function portions 25 are arranged in a row in the slow-axis direction at the fringe areas in the slow-axis direction in the incident surfaces 22 of the laser light emitted from the respective emitters 12 of the semiconductor laser element 11. As a result, high-angle light components diverging at angles of divergence large enough to be crosstalk light, among the light components diverging in the slow-axis direction of the laser light emitted from the respective emitters 12, can be deflected and corrected toward the optical axis C side of the emitters 12 by the spreading suppression function portions 25. And so, the laser light emitted from the first collimator lens 20 can be collimated in the slow-axis direction by the second collimator lens 30. More specifically, the spreading in the slow-axis direction is suppressed by the spreading suppression function portions 25 in the respective deflection correction lens portions 21 of the first collimator lens 20. The laser light emitted from the first collimator lens 20 can also be surely made incident on the corresponding lens elements 31 of the second collimator lens 30 so that the laser light is collimated in the slow-axis direction by the lens action of the lens elements 31.

And so, according to the semiconductor laser optical device of the foregoing configuration, the occurrence of crosstalk light can be reliably suppressed to obtain high collimating efficiency and improve the light utilization ratio. In addition, the collimating properties can be improved without using other optical members such as a beam splitter and a deflection mechanism. Consequently, a semiconductor laser optical device having desired performance can be fabricated with a small parts count in a cost advantageous manner, and the semiconductor laser optical device itself can be configured in a small size.

### Second Embodiment

FIG. 5 is a diagram schematically illustrating a configuration example of a semiconductor laser optical device according to a second embodiment of the present invention. FIG. 5(a) is a plan view taken in the fast-axis direction. FIG. 5(b) is an enlarged view illustrating the area circled by the broken line in FIG. 5(a).

The semiconductor laser optical device according to this second embodiment has the same configuration as that of the semiconductor laser optical device according to the foregoing first embodiment except that one having spreading suppression function portions at fringe areas in the slow-axis direction in both of its incident surface and emission surface is used as the first collimator lens 20 in the semiconductor laser optical device according to the first embodiment. In FIG. 5, the same components as those of the semiconductor laser optical device according to the first embodiment are designated by the same reference signs for the sake of convenience.

In this example, the first collimator lens 20 is formed so that, in a plane seen in the fast-axis direction (X-Z plane), V-shaped groove portions extend in the fast-axis direction in parallel with each other at areas of the flat surface of the plano-convex cylindrical lens opposed to the respective areas between the adjoining emitters. As a result, a plurality of incident side deflection correction lens portions 21A having a trapezoidal incident surface 22 convex toward the laser source 10 side are formed in the areas between the adjoining groove portions. The incident side deflection correction lens portions 21A are arranged in one example in the slow-axis direction so as to correspond to the respective emitters 12. V-shaped groove portions are also formed in the refracting surface of the plano-convex cylindrical lens at positions corresponding to the respective groove portions so as to extend in the fast-axis direction in parallel with each other. As a result, a plurality of emission side deflection correction lens portions 26 having a trapezoidal emission surface 27 convex toward the second collimator lens 30 side are formed in the areas between the adjoining groove portions. The emission side deflection correction lens portions 26 are arranged in one example in the slow-axis direction so as to correspond to the respective emitters 12. And so, in this first collimator lens 20, the concave inclined surfaces 22A of each incident side deflection correction lens portion 21A constitute first spreading suppression function portions 25A. At the same time, convex inclined surfaces 27A of each emission side deflection correction lens portion 26 constitute second spreading suppression function portions 25B.

The concave inclined surfaces 22A of the incident side deflection correction lens portions 21A and the convex inclined surfaces 27A of the emission side deflection correction lens portions 26 may be formed at the same inclination angle or different inclination angles.

In this semiconductor laser optical device, light components of the laser light emitted from one emitter 12, diverging at large angles of divergence in the slow-axis direction while traveling, are incident on the concave inclined surfaces 22A of the incident side deflection correction lens portion 21A of the first collimator lens 20 corresponding to the emitter 12. High-angle light components incident on the convex inclined surfaces 22A are deflected toward the optical axis C side of the emitter 12 by the action of the first spreading suppression function portions 25A. And so, according to such a configuration, the light components can be further deflected and corrected toward the optical axis C side of the emitter 12 when the light components are emitted from the convex inclined surfaces 27A of the emission side deflection correction lens portions 26. Moreover, light that has failed to be deflected by the first spreading suppression function portions 25A can be deflected and corrected again by the action of the second spreading suppression function portions 25B. This can increase the flexibility of lens design for improving the collimating properties.

### Third Embodiment

FIG. 6 is a diagram schematically illustrating a configuration example of a semiconductor laser optical device according to a third embodiment of the present invention. FIG. 6(a) is a plan view taken in the fast-axis direction. FIG. 6(b) is an enlarged view illustrating the area circled by the broken line in FIG. 6(a).

The semiconductor laser optical device according to this third embodiment has the same configuration as that of the semiconductor laser optical device according to the foregoing first embodiment except that one having a slow-axis direction defection correction function using reflection is used as the first collimator lens 20 in the semiconductor laser optical device according to the first embodiment. In FIG. 6, the same components as those of the semiconductor laser optical device according to the first embodiment are designated by the same reference signs for the sake of convenience.

In this example, the first collimator lens 20 is formed so that, in a plane seen in the fast-axis direction (X-Z plane), trapezoidal notches convex toward the second collimator lens 30 side in the Z-axis direction extend in the slow-axis direction in parallel with each other in areas of the flat surface of the plano-convex cylindrical lens opposed to the respective areas between the adjoining emitters. As a result, a plurality of truncated pyramidal deflection correction lens portions 21 are formed in the areas between the adjoining notches. The deflection correction lens portions 21 are arranged in one example in the slow-axis direction so as to correspond to the respective emitters 12. The flat surfaces of the respective deflection correction lens portions 21 are configured to serve as incident surfaces 22 on which the laser light from the emitters 12 is incident. Inside surfaces 23 of the respective deflection correction lens portions 21 are formed at an inclination angle such that high-angle light components of the laser light from the emitter 12 incident on the flat surface of the deflection correction lens portion 21, diverging at relatively large angles of divergence in the slow-axis direction, are critically reflected (totally reflected). And so, this first collimator lens 20 is configured to have a slow-axis direction deflection correction function of totally reflecting the high-angle light components by the inside surfaces 23 of the deflection correction lens portions 21, thereby deflecting and correcting the high-angle light components toward the optical axis C side of the emitters 12 in the slow-axis direction.

The semiconductor laser optical device having such a configuration can also provide the same effects as those of the semiconductor laser optical device according to the foregoing first embodiment.

### Fourth Embodiment

FIG. 7 is a diagram schematically illustrating a configuration example of a semiconductor laser optical device according to a fourth embodiment of the present invention. FIG. 7(a) is a plan view taken in the fast-axis direction. FIG. 7(b) is an enlarged view illustrating the area circled by the broken line in FIG. 7(a).

The semiconductor laser optical device according to this fourth embodiment has the same configuration as that of the semiconductor laser optical device according to the foregoing first embodiment except that one having a slow-axis direction deflection correction function using reflection is used as the first collimator lens 20 in the semiconductor laser optical device according to the first embodiment. In FIG. 7, the same components as those of the semiconductor laser optical device according to the first embodiment are designated by the same reference signs for the sake of convenience.

In this example, the first collimator lens 20 is formed so that, in a plane seen in the fast-axis direction (X-Z plane), trapezoidal recesses 28 convex toward the laser source in the Z-axis direction extend in the slow-axis direction in parallel with each other in areas of the flat surface of the plano-convex cylindrical lens opposed to the respective areas between the adjoining emitters. A reflective film 29 is further formed on the surfaces of inclined inside surfaces 28A of the recesses 28. Flat inner end surfaces of the respective recesses 28 are configured to serve as incident surfaces 22 on which the laser light from the emitters is incident. In this first collimator lens 20, high-angle light components of the laser light from the emitters 12 incident on the inside of the recesses 28 through the openings of the recesses 28, diverging at relatively large angles of divergence in the slow-axis direction, are reflected by the reflective film 29. And so, this first collimator lens 20 is configured to have a slow-axis direction deflection correction function of deflecting and correcting the high-angle light components toward the optical axis C side of the emitters 12 in the slow-axis direction.

The inclination angle of the inside surfaces 28A of the respective recesses 28 is set in such an angle range that the sign of the inclination of the angle of light incident on the inner end surface of the recess 28 serving as the incident surface 22 coincides with the sign of the inclination of the angle of light incident on the incident surface 32 of the corresponding lens element 31 of the second collimator lens 30.

The reflective film 29 may preferably have a high reflection characteristic (for example, not lower than 90%) in the wavelength band of the laser light emitted from the semiconductor laser element 11. For example, such a reflective film 29 maybe made of aluminum. For example, the reflective film 29 may have a thickness of 100 to 200 μm.

In the semiconductor laser optical device of this example, the separation distance in the optical axis direction (Z-axis direction) between the flat surface of the first collimator lens 20 in which the recesses 28 are formed and the edges of the emitters 12 from which the laser light is emitted is set to be smaller than that of the semiconductor laser optical device according to the first embodiment. The reason is to surely make the laser light from the emitters 12 incident on the inside of the corresponding recesses 28 of the first collimator lens 20.

The semiconductor laser optical device having such a configuration can also provide the same effects as those of the semiconductor laser optical device according to the foregoing first embodiment.

Examples of experiments that were conducted to confirm the effects of the present invention will be described below.

### EXPERIMENT EXAMPLE 1

A semiconductor laser optical device according to the present invention, having the specifications described below was fabricated according to the configuration illustrated in FIG. 1. A condenser lens was arranged on the emission side of the second collimator lens, and an optical fiber (outside diameter of φ0.40 mm) was arranged so that its incident end surface was located at the focus position of the condenser lens. Alight flux incident on the optical fiber was measured. As a result, the light utilization ratio was found to be 98.8%. Here, the light utilization ratio is expressed by a value obtained by dividing the magnitude of the light flux incident on the optical fiber by the magnitude of the total flux including light components with which the incident surface of the optical fiber is not irradiated. The irradiation spot formed on the incident end surface of the optical fiber had a dimension of ±0.08 mm in the fast-axis direction and ±0.2 mm in the slow-axis direction. From the result, it was shown that equivalent collimating properties can be obtained in the fast-axis direction and the slow-axis direction.

### Specifications of Semiconductor Laser Optical Device

[Laser Source (10)]

Semiconductor laser element (11)
Outside dimensions (X-axis direction×Y-axis direction×Z-axis direction); 4 mm×0.1 mm×1.5 mm
The number of emitters; five
Dimensions of the laser light emission edge of one emitter (X-axis direction×Y-axis direction); 40 μm×0.1 μm
The center-to-center distance (arrangement pitch) p between adjoining emitters; 200 μm
The oscillation wavelength of the laser light; 638 nm
The angle of divergence of the laser light in the fast-axis direction with respect to the optical axis of the emitter; ±48° in the total angle at half maximum
The angle of divergence of the laser light in the slow-axis direction with respect to the optical axis of the emitter; ±13° in the total angle at half maximum
Output; 8 W

[First Collimator Lens (20)]
Dimension in the optical axis direction (Z-axis direction); 0.8 mm
Refractive index; 1.78
The inclination angle of the concave inclined surfaces in the deflection correction lens portions; 5°
The separation distance in the optical axis direction (Z-axis direction) between the flat surface of the incident surface and the laser light emission edges of the emitters; 0.16 mm
The angle (θ1) of light incident on the concave inclined surfaces of the respective lens portions; 10.8°

[Second Collimator Lens (30)]
The radius of curvature of each lens element; 0.81 mm
Refractive index; 1.81
The minimum separation distance in the optical axis direction (Z-axis direction) between the incident surface of the lens element and the emission surface of the first collimator lens; 1.1 mm

### COMPARATIVE EXPERIMENT EXAMPLE 1

A comparative semiconductor laser optical device having the same configuration as that of the semiconductor laser optical device according to experiment example 1 was fabricated except that one having no spreading suppression function portion (see FIG. 4-C) was used as the first collimator lens in the semiconductor laser optical device fabricated in experiment example 1. The light utilization ratio of this comparative semiconductor laser optical device was determined by the same method as in experiment example 1 and found to be 92%.

### EXPERIMENT EXAMPLE 2

A semiconductor laser optical device according to the present invention, having the same configuration as that of experiment example 1 was fabricated except that one having the configuration illustrated in FIG. 6 was used as the first collimator lens in the semiconductor laser optical device fabricated in experiment example 1. This first collimator lens has the specifications described below. The light utilization ratio of this semiconductor laser optical device was determined by the same method as in experiment example 1 and found to be 96%. The irradiation spot formed on the incident end surface of the optical fiber had a dimension of 0.08 mm in the fast-axis direction and 0.2 mm in the slow-axis direction. From the result, it was shown that equivalent collimating properties can be obtained in the fast-axis direction and the slow-axis direction.

### Specifications of First Collimator Lens

Dimension in the optical axis direction (Z-axis direction); 0.8 mm
Refractive index; 1.78
The inclination angle of the inside surfaces of the deflection correction lens portions; 0.5°
The separation distance in the optical axis direction (Z-axis direction) between the incident surfaces of the deflection correction lens portions and the laser light emission edges of the emitters; 0.15 mm
The angle of light incident on the incident surfaces of the deflection correction lens portions; 10°

### EXPERIMENT EXAMPLE 3

A semiconductor laser optical device according to the present invention, having the same configuration as that of experiment example 1 was fabricated except that one having the configuration illustrated in FIG. 7 was used as the first collimator lens in the semiconductor laser optical device fabricated in experiment example 1. This first collimator lens has the specifications described below. The light utilization ratio of this semiconductor laser optical device was determined by the same method as in experiment example 1 and found to be 95%. The irradiation spot formed on the incident end surface of the optical fiber had a dimension of 0.08 mm in the fast-axis direction and 0.2 mm in the slow-axis direction. From the result, it was shown that equivalent collimating properties can be obtained in the fast-axis direction and the slow-axis direction.

### Specifications of First Collimator Lens

Dimension in the optical axis direction (Z-axis direction); 0.8 mm
Refractive index; 1.78
The dimension of the openings of the recesses in the slow-axis direction; 0.5 mm
The inclination angle of the inside surfaces of the recesses; 0.5°
The separation distance in the optical axis direction (Z-axis direction) between the flat surface and the laser light emission edges of the emitters; 0.16 mm
The angle of light incident on the incident surfaces of the recesses; 10°
The material of the reflective film; aluminum
The reflectance of the reflective film to the wavelength of the laser light; 90%
The thickness of the reflective film; 100 μm

As described above, it was confirmed that according to the semiconductor laser optical device of the present invention, a high light utilization ratio can be obtained as compared with the comparative semiconductor laser optical device, and so high collimating efficiency can be obtained.

While the embodiments of the present invention have been described above, the present invention is not limited to the foregoing embodiments and various modifications may be made thereto.

For example, the spreading suppression function portions of the semiconductor laser optical device according to the first embodiment and the first spreading suppression function portions of the semiconductor laser optical device according to the second embodiment may be constituted by convex inclined surfaces. The second spreading suppression function portions of the semiconductor laser optical device according to the second embodiment may be constituted by concave inclined surfaces.

The laser source is not limited to an array type in which a plurality of emitters are arranged in a row in the slow-axis direction. For example, a plurality of chip-shaped semiconductor laser elements each including a plurality of emitters arranged in a row in the slow-axis direction maybe stacked in the fast-axis direction.

### REFERENCE SIGNS LIST

10 Laser source

11 Semiconductor laser element

12 Emitter

20 First collimator lens

21 Deflection correction lens portion

21A Incident side deflection correction lens portion

22 Incident surface

22A Concave inclined surface

23 Inside surface

25 Spreading suppression function portion

25A First spreading suppression function portion

25B Second spreading suppression function portion

26 Emission side deflection correction lens portion

27 Emission surface

27A Convex inclined surface

28 Recess

28A Inside surface

29 Reflective film

30 Second collimator lens

31 Lens element

32 Incident surface

35 Emission surface

40 Fast-axis direction collimator lens

50 Slow-axis direction collimator lens

51, 51a, 51b, 51c Lens element

C Optical axis of emitter

1. A semiconductor laser optical device comprising:
a laser source that includes a semiconductor laser element;
a first collimator lens that is provided on a laser light emission side of the laser source and collimates a light component diverging in a fast-axis direction of laser light emitted from the laser source; and
a second collimator lens that is provided on an emission side of the first collimator lens and collimates a light component diverging in a slow-axis direction of light emitted from the first collimator lens, wherein
the first collimator lens has a function of making light of which spreading in the slow-axis direction is suppressed incident on the second collimator lens.

2. The semiconductor laser optical device according to claim 1, wherein the first collimator lens has a spreading suppression function portion at a fringe area in the slow-axis direction in either one or both of an incident surface and an emission surface thereof.

3. The semiconductor laser optical device according to claim 1, wherein the semiconductor laser element constituting the laser source is configured such that a plurality of emitters are arranged in a row.

4. The semiconductor laser optical device according to claim 2, wherein the semiconductor laser element constituting the laser source is configured such that a plurality of emitters are arranged in a row.
